(19) United States
(12) Patent Application Publication
(10) Pub. No.: US 2008/0017859 A1
(43) Pub. Date: Jan. 24, 2008

(54) SYSTEM FOR DISPLAYING IMAGES INCLUDING THIN FILM TRANSISTOR DEVICE AND METHOD FOR FABRICATING THE SAME

(75) Inventors: Yi-Wen Tai, Hsinchu City (TW); Cheng-Hsin Chen, Changhua County (TW); Jr-Hong Chen, Hsinchu County (TW)

Correspondence Address: THOMAS, KAYDEN, HORSTEMEYER & RISLEY, LLP, 600 GALLERIA PARKWAY, STE 1500, ATLANTA, GA, 30339, US

(73) Assignee: TPO DISPLAYS CORP., Miao-Li County (TW)

(21) Appl. No.: 11/458,118

(22) Filed: Jul. 18, 2006

(51) Int. Cl. H01L 29/04; H01L 29/10; H01L 31/00

(52) U.S. Cl. 257/59

(57) ABSTRACT

A system for displaying images comprises a thin film transistor (TFT) device comprising a substrate having a pixel region and a terminal region. A first conductive layer is disposed on the substrate, comprising a gate electrode for a thin film transistor in the pixel region and at least one track in the terminal region. An interlayer dielectric layer is disposed on the substrate, covering the thin film transistor and the track. A second conductive layer is disposed on the interlayer dielectric layer in the pixel region, electrically connected to the thin film transistor to serve as a source/drain electrode thereof and electrically connected to the track in the terminal region. A planarization layer is disposed on the interlayer dielectric layer in the pixel region.

### BACKGROUND OF THE INVENTION

1. Field of the Invention

The invention relates to flat panel display (FPD) technology, and in particular to a thin film transistor (TFT) device having an anti-scratch structure in the terminal region to improve device reliability, and a method for fabricating a thin film transistor (TFT) device with the anti-scratch protection.

2. Description of the Related Art

A display module typically includes a thin film transistor (TFT) device disposed on a panel utilized to control and drive the panel. FIG. 1 illustrates a conventional TFT device for a display module. The TFT device includes a substrate 100 comprising a pixel region 10 and a terminal region 20. A plurality of thin film transistors (TFTs) and a plurality of storage capacitors are disposed in the pixel region 10 of the substrate 100. In order to simplify the diagram, only a TFT 113 and a storage capacitor 121 are depicted. Typically, the TFT 113 includes an active layer 102 comprising drain/source regions 102b and a channel region 102a, a gate dielectric layer 104 formed on the active layer 102, a gate electrode 106 disposed on the gate dielectric layer 104 and drain/source electrodes 112 electrically connected to the drain/source regions 102b via an interlayer dielectric (ILD) layer 110 covering the TFT 113 in the pixel region 10 and the substrate 100 in the terminal region 20. Moreover, the storage capacitor 121 comprises a top electrode 120 and a bottom electrode 108 and a capacitor dielectric interposed therebetween. The ILD layer 110 and an overlying planarization layer 118 may serve as the capacitor dielectric. The top electrode 120 is electrically connected to the source/drain electrode 112 via the planarization layer 118 and may serve as a pixel electrode.

A plurality of tracks and a plurality of pads are disposed between the ILD layer 110 and an overlying planarization layer 118 in the terminal region 20 of the substrate 100. Also, In order to simplify the diagram, only a track 114 and a pad 116 are depicted. The track 114 is electrically connected to the date line (not shown) in the pixel region 10. Moreover, a conductive plug 122 is electrically connected to the pad 116 via the planarization layer 118, thereby electrically connecting the pad 116 and a driving IC (not shown).

After the TFT device is incorporated into a display module, the track 114 and pad 116 in the terminal region 20 are only protected by the planarization layer 118. The planarization layer 118 which comprises acrylic-like material, however, easily cracks when the planarization layer 118 is scratched. Moreover, the tracks or pads comprising a soft metal material, such as Mo/Al/Mo, may be deformed or produce metal burrs due to the influence of the external force, causing the neighboring tracks or pads to short. As a result, the device reliability is reduced and the fabrication cost is increased.

Thus, there exists a need in the art for development of an anti-scratch structure in the terminal region which can prevent the tracks or pads from shorting to improve device reliability.

### BRIEF SUMMARY OF THE INVENTION

A detailed description is given in the following embodiments with reference to the accompanying drawings. A system for displaying images and a method for fabricating the same are provided. An embodiment of a system for displaying images comprises a thin film transistor device comprising a substrate. The substrate comprising a pixel region and a terminal region. A first conductive layer is disposed on the substrate, comprising a gate electrode for a thin film transistor in the pixel region and at least one track in the terminal region. An interlayer dielectric layer is disposed on the substrate to cover the thin film transistor in the pixel region and the track in the terminal region. A second conductive layer is disposed on the interlayer dielectric layer in the pixel region, electrically connected to the thin film transistor to serve as a source/drain electrode thereof and electrically connected to the track in the terminal region. A planarization layer is disposed on the interlayer dielectric layer in the pixel region.

An embodiment of a method for fabricating a system for displaying images, wherein the system comprises a thin film transistor device, the method comprising providing a substrate. The substrate comprises a pixel region and a terminal region. A first conductive layer is formed on the substrate, wherein the first conductive layer comprises a gate electrode for a thin film transistor in the pixel region and at least one track in the terminal region. The gate electrode in the pixel region and the track in the terminal region are covered with an interlayer dielectric layer. A first contact hole is formed in the interlayer dielectric layer in the pixel region to expose a source/drain region of the thin film transistor. A second conductive layer is formed on the interlayer dielectric layer in the pixel region and fills the first contact hole to serve as a source/drain electrode for the thin film transistor, wherein the second conductive layer is electrically connected to the track in the terminal region. A planarization layer is formed on the interlayer dielectric layer in the pixel region.

### BRIEF DESCRIPTION OF THE DRAWINGS

The invention can be more fully understood by reading the subsequent detailed description and examples with references made to the accompanying drawings, wherein:

FIG. 1 is a cross section of a conventional thin film transistor device for a display module;

FIGS. 2A to 2E are cross sections of an embodiment of a method for fabricating a system for displaying images incorporating a thin film transistor device;

FIG. 3 is a plane view of a flat panel display module having a thin film transistor device shown in FIG. 2E; and

FIG. 4 schematically shows another embodiment of a system for displaying images.

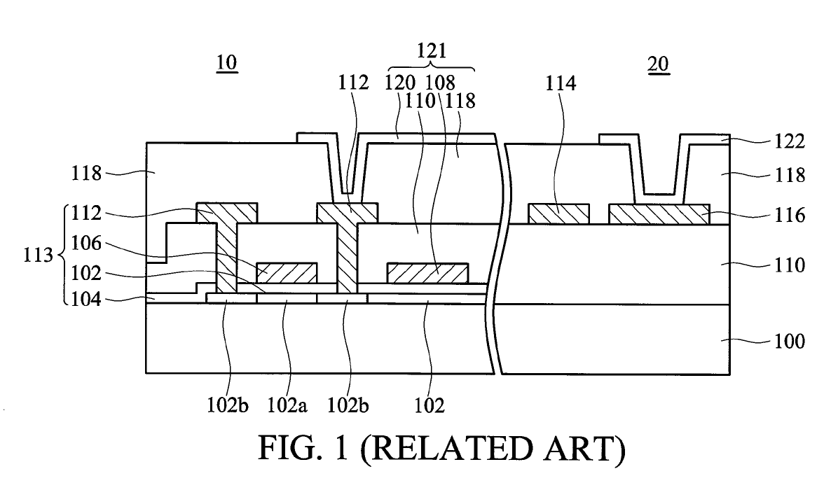

### DETAILED DESCRIPTION OF THE INVENTION

The following description is of the best contemplated mode of carrying out the invention. This description is made for the purpose of illustrating the general principles of the invention and should not be taken in a limiting sense. The scope of the invention is best determined by reference to the appended claims.

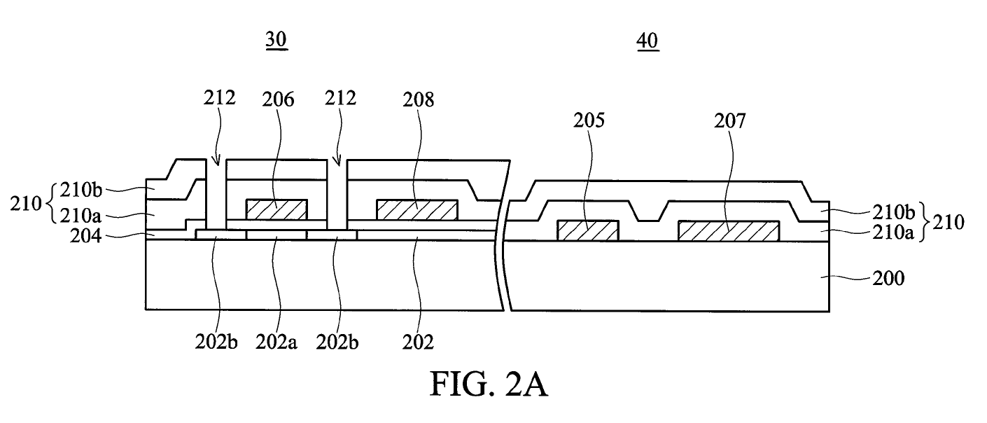

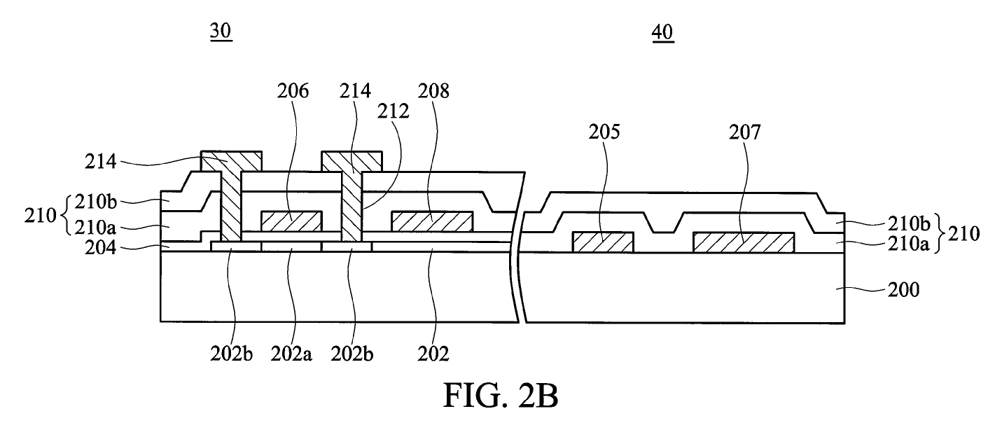

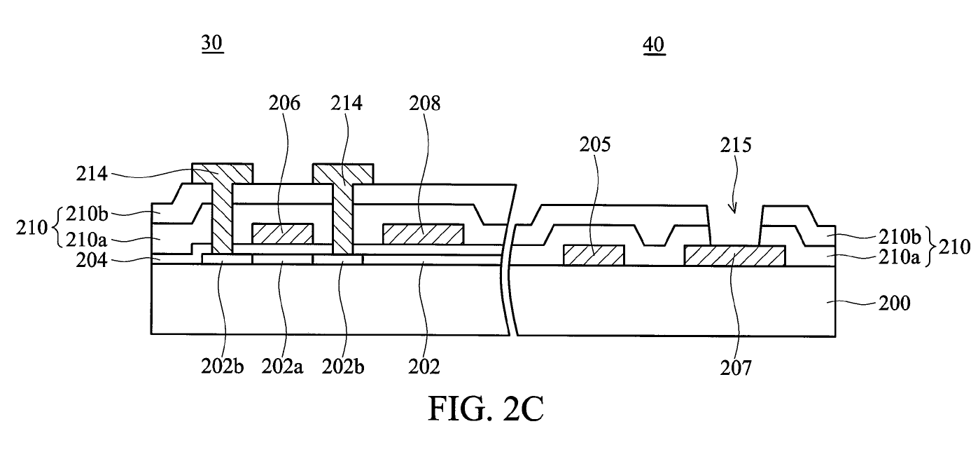

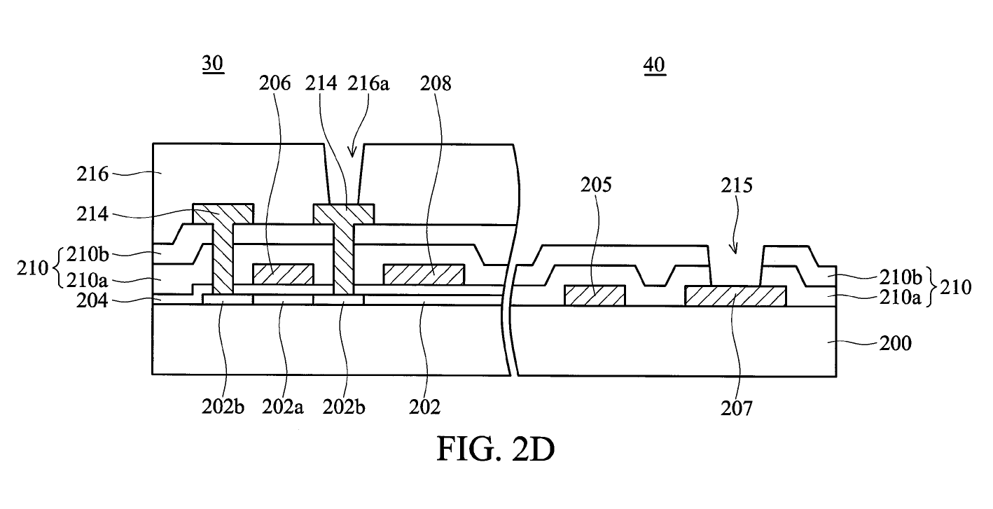

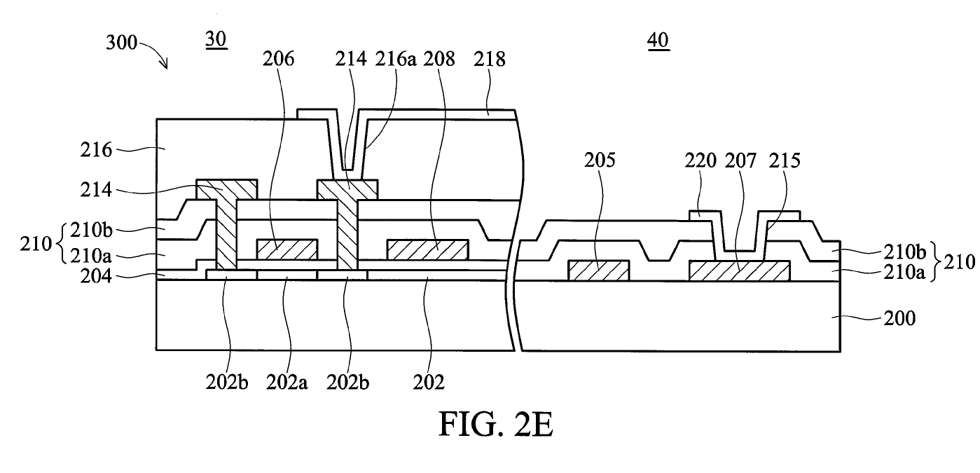

Systems for displaying images and fabrication methods for same are provided. FIG. 2E illustrates an exemplary embodiment of such a system. Specifically, the system incorporates a thin film transistor (TFT) device 300 comprising a substrate 200 comprising a pixel region 30 and a terminal region 40. An active layer 202 is disposed on the substrate 200 of the pixel region 30. The active layer 202 may comprise at least one pair of source/drain regions 202b and at least one intermediate channel region 202a at a region for formation of a thin film transistor (TFT). A gate dielectric layer 204, such as a silicon oxide layer, a silicon nitride layer or a combination thereof, covers the active layer 202 and exposes the pair of source/drain regions 202b.

A first conductive layer for definition of gate line is disposed on the substrate 200. In this embodiment, the first conductive layer may comprise a gate electrode 206 for a TFT, extending from a gate line (not shown) and a bottom electrode 208 for a storage capacitor in the pixel region 30. Moreover, the first conductive layer further comprises at lest one track 205 and at least one pad 207 disposed on the substrate 200 of the terminal region 40. A second conductive layer for definition of a date line is disposed on an interlayer dielectric (ILD) layer 210. The second conductive layer may comprise source/drain electrodes 214 electrically connected to the exposed drain/source regions 202b via the ILD layer 210. Moreover, one of the source/drain electrodes 214 extends from the date line (not shown) and is electrically connected to the track 205 in the terminal region 40. In this embodiment, the ILD layer 210 may comprise a silicon oxide layer 210a with a thickness of about 3000A and an overlying silicon nitride layer 210b with a thickness of about 3000 Å. Moreover, the ILD layer 210 in the terminal region 40 is employed for anti-scratch protection.

A planarization layer 216 is disposed on the ILD layer 210 in the pixel region 30 and exposes one of the source/drain regions 214. The planarization layer 216 and the ILD layer 210 may serve as a capacitor dielectric for the storage capacitor. A third conductive layer comprising a first portion 218 disposed on the planarization layer 216 and electrically connected to one of the source/drain regions 214 via the planarization layer 216, and a second portion 220 disposed on the interlayer dielectric layer 210 in the terminal region 40 and electrically connected to the pad 207 via interlayer dielectric layer 210. The first portion 218 of the third conductive layer may serve as a top electrode of the storage capacitor and a pixel electrode for a display device, such as an LCD or OELD device.

FIGS. 2A to 2E illustrate an embodiment of a method for fabricating a system for displaying images incorporating a thin film transistor device 300. In FIG. 2A, a substrate 200 comprising a pixel region 30 and a terminal region 40 is provided. The substrate 200 may comprise a flexible material, such as polymer, or a transparent material, such as glass. An active layer 202, such as a polysilicon layer, is formed on the substrate 200 of the pixel region 30. The active layer 202 may comprise at least one pair of source/drain regions 202b and at least one intermediate channel region 202a at a region for formation of a thin film transistor (TFT) in subsequent steps. Next, a gate dielectric layer 204 is formed on the substrate 200 and covers the active layer 202 by conventional deposition, such as CVD. In some embodiments, the gate dielectric layer 204 may comprise silicon oxide, silicon nitride or a combination thereof.

A first conductive layer is subsequently formed on the gate dielectric layer 204 in the pixel region 30 and covers the substrate 200 in the terminal region 40 by conventional deposition, such as CVD or sputtering. Thereafter, the first conductive layer is patterned by conventional lithography and etching to form a gate line (not shown), a gate electrode 206 extending from the gate line and a bottom electrode 208 for a storage capacitor in the pixel region 30, and form at least one track 205 and at least one pad 207 in the terminal region 40. In this embodiment, the first conductive layer may comprise molybdenum (Mo).

An ILD layer 210 is formed on the gate dielectric layer 204 and covers the gate electrode 206 and the bottom electrode 208 in the pixel region 30 and the track 205 and the pad 207 in the terminal region 40 by conventional deposition, such as CVD. The ILD layer 210 may comprise a single insulating layer or multiple insulating layers. In this embodiment, for example, the ILD layer 210 may comprise a silicon oxide layer 210a with a thickness of about 3000 Å and an overlying silicon nitride layer 210b with a thickness of about 3000 Å. Additionally, the ILD layer 210 in the terminal region 40 is utilized to protect the underlying track 206 and pad 207 from scratching. Next, the ILD layer 210 and the gate dielectric layer 204 are successively etched to form first contact holes 212 therein and expose the source/drain regions 202b in the active layer 202.

In FIG. 2B, a second conductive layer (not shown) is formed on the ILD layer 210 and fills the first contact holes 212. In this embodiment, for example, the second conductive layer may comprise a Mo/Al/Mo layer and be formed by conventional deposition, such as CVD or sputtering. The second conductive layer is subsequently patterned by conventional lithography and etching to form a data line (not shown) and source/drain electrodes 214, thus, fabrication of a thin film transistor is complete. The data line is electrically connected to the track 205 in subsequent steps. Next, the ILD layer 210 in the terminal region 40 is etched to form a second contact hole 215 therein and expose a portion of pad 207, as shown in FIG. 2C.

In FIG. 2D, a planarization layer 216 is formed on the ILD layers and covers the source/drain electrodes 214 in the pixel region 30. The planarization layer 216 may comprise acrylic-like material. Next, the planarization layer 216 in the terminal region 40 is removed by etching, to expose the ILD 210 and the pad 207. The remaining planarization layer 216 in the pixel region 30 is etched to form a third contact hole 216a therein and above one of the first contacts 214 to expose one of the source/drain electrodes 214. In this embodiment, the planarization layer 216 and the underlying ILD layer 210 may serve as a capacitor dielectric.

In FIG. 2E, a third conductive layer (not shown) is formed on the planarization layer 216 and fills the second and third contact holes 215 and 216a. In this embodiment, the third conductive layer may comprise a transparent conductive material, such as indium tin oxide (ITO). The third conductive layer is subsequently patterned by conventional lithography and etching, to form a pixel electrode 218 in the pixel region 30 and a conductive plug 220 in the terminal region 30, electrically connected to the pad 116 via the ILD layer 210. The pixel electrode 218 may also serve as a top electrode for the storage capacitor. As a result, fabrication of a thin film transistor device 300 of the invention is complete.

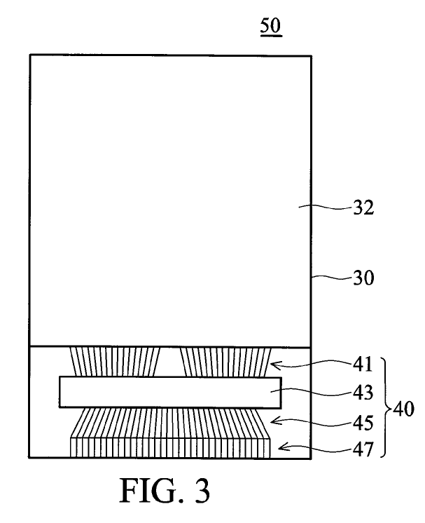

FIG. 3 illustrates a flat panel display module having the thin film transistor device shown in FIG. 2E. The flat panel display module 50 comprises a display device 32 incorporating the thin film transistor device shown in FIG. 2E. The display device 32, such as an OLED or LCD device is disposed corresponding to the pixel region 30 of the thin film transistor device. The terminal region 40 comprises a fan in region 41, a pad region (not shown), a fan out region 45 and a flexible printed circuit (FPC) fan out region 47. A driving IC 43 is disposed in the pad region and electrically connected to the pads (not shown) thereon. Moreover, the driving IC 43 is electrically connected to the display device 43 via the tracks disposed in the fan in region 41 and electrically connected to the external circuit (not shown) via the fan out region 45 and the FPC fan out region 47. As mentioned, an ILD layer (not shown) covers the tracks in the fan in region 41, the fan out region 45 and the FPC fan out region 47 to serve as a protective layer for anti-scratch protection.

According to invention, since the tracks and pads in the terminal region of the semiconductor device can be protected by a stack of the silicon oxide layer and the silicon nitride layer (i.e. an ILD layer), the scratch problem can be reduced due to enhancement of mechanical strength. Moreover, since the tracks and pads comprising Mo of the invention also has a better mechanical strength compared to the conventional tracks and pads comprising Mo/Al/Mo, deformation of tracks and pads of the invention can be prevented when an external force is applied in the terminal region of the semiconductor device. Accordingly, the device reliability can be increased, thereby reducing the fabricating cost.

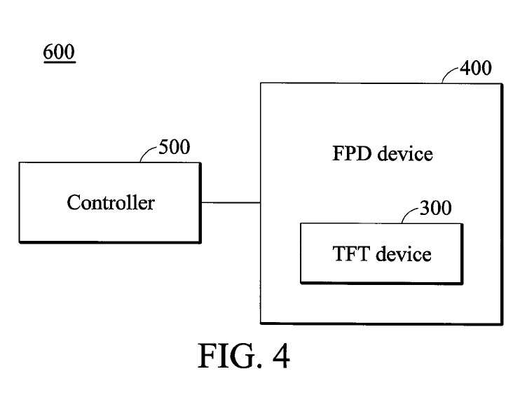

FIG. 4 schematically shows another embodiment of a system for displaying images which, in this case, is implemented as a flat panel display (FPD) device 400 or an electronic device 600 such as a laptop computer, a mobile phone, a digital camera, a personal digital assistant (PDA), a desktop computer, a television, a car display or a portable DVD player. The described TFT device can be incorporated into the flat panel display device 400 that can be an LCD or OLED panel. As shown in FIG. 4, the FPD device 400 may comprise a TFT device, such as a TFT device 300 shown in FIG. 2E. In some embodiments, the TFT device 300 can be incorporated into the electronic device 600. As shown in FIG. 4, the electronic device 600 comprises the FPD device 400 and a controller 500. Moreover, the controller 500 is coupled to the FPD device 400 and operative to control the FPD device 400 to render images in accordance with input (e.g. image signals).

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A system for displaying images, comprising:
a thin film transistor device, comprising:
a substrate comprising a pixel region and a terminal region;
a first conductive layer disposed on the substrate, comprising a gate electrode for a thin film transistor in the pixel region and at least one track in the terminal region;
an interlayer dielectric layer disposed on the substrate to cover the thin film transistor in the pixel region and the track in the terminal region;
a second conductive layer disposed on the interlayer dielectric layer in the pixel region, electrically connected to the thin film transistor to serve as a source/drain electrode thereof and electrically connected to the track in the terminal region; and
a planarization layer disposed on the interlayer dielectric layer in the pixel region.

2. The system as claimed in claim 1, wherein the first conductive layer further comprises at least one pad partially covered by the interlayer dielectric layer in the terminal region.

3. The system as claimed in claim 2, wherein the thin film transistor device further comprises a third conductive layer comprising a first portion disposed on the planarization layer and electrically connected to the second conductive layer via the planarization layer, and a second portion disposed on the interlayer dielectric layer in the terminal region and electrically connected to the pad via the interlayer dielectric layer.

4. The system as claimed in claim 3, wherein the third conductive layer comprises indium tin oxide (ITO).

5. The system as claimed in claim 1, wherein the first conductive layer comprises molybdenum (Mo).

6. The system as claimed in claim 1, wherein the interlayer dielectric layer comprises a silicon oxide layer and an overlying silicon nitride layer.

7. The system as claimed in claim 1, wherein the second conductive layer comprises a Mo/Al/Mo layer.

8. The system as claimed in claim 1, further comprising:
a flat panel display device comprising the thin film transistor device; and
a controller coupled to the flat panel display device, being operative to control the flat panel display device to render images in accordance with input.

9. The system as claimed in claim 8, wherein the system comprises an electronic device comprising the flat panel display device.

10. The system as claimed in claim 9, wherein the electronic device is a laptop computer, a mobile phone, a digital camera, a personal digital assistant, a desktop computer, a television, a car display or a portable DVD player.

11. A method for fabricating a system for displaying images, wherein the system comprises a thin film transistor device, the method comprising:
providing a substrate comprising a pixel region and a terminal region;
forming a first conductive layer on the substrate, wherein the first conductive layer comprises a gate electrode for a thin film transistor in the pixel region and at least one track in the terminal region;
covering the gate electrode in the pixel region and the track in the terminal region with an interlayer dielectric layer;
forming a first contact hole in the interlayer dielectric layer in the pixel region to expose a source/drain region of the thin film transistor;
forming a second conductive layer on the interlayer dielectric layer in the pixel region and filling into the first contact hole to serve as a source/drain electrode for the thin film transistor, wherein the second conductive layer is electrically connected to the track in the terminal region; and
forming a planarization layer on the interlayer dielectric layer in the pixel region.

12. The method as claimed in claim 11, wherein the first conductive layer further comprises at least one pad partially covered by the interlayer dielectric layer in the terminal region.

13. The method as claimed in claim 12, further comprising forming a second contact hole in the interlayer dielectric layer above the pad prior to formation of the planarization layer.

14. The method as claimed in claim 13, further comprising:
forming a third contact hole in the planarization layer above the first contact hole; and
filling the second and third contact holes with a third conductive layer.

15. The method as claimed in claim 14, wherein the third conductive layer comprises indium tin oxide.

16. The method as claimed in claim 11, wherein the first conductive layer comprises molybdenum.

17. The method as claimed in claim 11, wherein the interlayer dielectric layer comprises a silicon oxide layer and an overlying silicon nitride layer.

18. The method as claimed in claim 11, wherein the second conductive layer comprises a Mo/Al/Mo layer.
